(19) United States
(12) Patent Application Publication
(10) Pub. No.: US 2011/0234290 A1
(43) Pub. Date: Sep. 29, 2011

(54) SWITCHED-CAPACITOR CURRENT REFERENCE WITH REDUCED OUTPUT RIPPLE

(76) Inventor: Venkataramanan Ramamurthy, Bangalore (IN)

(21) Appl. No.: 12/730,734

(22) Filed: Mar. 24, 2010

(51) Int. Cl. H03L 5/00

(52) U.S. Cl. 327/332

(57) ABSTRACT

A switched-capacitor current reference contains an amplifier, a current mirror circuit and a feedback circuit. In an embodiment, the feedback circuit receives a time-varying voltage waveform at a node connected to a switched-capacitor block used within the current mirror circuit, and is operated to provide a constant voltage waveform on an input terminal of the amplifier. Ripple in the output reference current provided by the switched-capacitor current reference is minimized or eliminated.

### BACKGROUND

1. Technical Field

Embodiments of the present disclosure relate generally to switched-capacitor circuits, and more specifically to a switched-capacitor current reference with reduced output ripple.

2. Related Art

A current reference is, generally, a circuit that provides as an output a current of substantially constant value, irrespective of the load value through which the current is passed. Output ripple of a current reference refers to variations in the value of the output current of the current reference from the desired constant value (ignoring variations caused due to noise, which may inherently be present in voltages and currents in circuits, as is well known in the relevant arts).

A switched-capacitor current reference is a current reference that is implemented using switched-capacitor techniques, employing one or more capacitors that are operated in a switched manner, with the capacitors operated to be alternately charged and discharged by the use of corresponding switches.

### SUMMARY

This Summary is provided to comply with 37 C.F.R. §1.73, requiring a summary of the invention briefly indicating the nature and substance of the invention. It is submitted with the understanding that it will not be used to interpret or limit the scope or meaning of the claims.

A switched-capacitor current reference is implemented with an amplifier, a current mirror circuit and a feedback circuit. The amplifier generates an amplified output as the difference of a feedback signal and a constant reference voltage received on corresponding input terminals. The current mirror circuit receives the amplified output and provides a reference current on an output node of the switched-capacitor current reference. The current mirror circuit contains a switched-capacitor block to operate as a resistor to set the value of the reference current. The value of the reference current is also based on the value of the constant reference voltage. The feedback circuit receives a time-varying voltage waveform at a node in the current mirror circuit, and generates the feedback signal as a constant voltage.

Embodiments of the present disclosure are described below with reference to examples for illustration. It should be understood that numerous specific details, relationships, and methods are set forth to provide a full understanding of the embodiment. One skilled in the relevant art, however, will readily recognize that the invention can be practiced without one or more of the specific details, or with other methods, etc.

### BRIEF DESCRIPTION OF THE VIEWS OF DRAWINGS

Example embodiments will be described with reference to the accompanying drawings briefly described below.

FIG. 1 is a block diagram of an example device in which several embodiments can be implemented.

FIG. 2A is a circuit diagram of a prior switched-capacitor current reference.

FIG. 2B is diagram illustrating clock waveforms used in operation of switched-capacitor current references of FIG. 2A, FIG. 3 and FIG. 6.

FIG. 2C is diagram illustrating voltage variations at a node of a prior switched-capacitor current reference.

FIG. 2D is a diagram illustrating the frequency components of the output current of a prior switched-capacitor current reference.

FIG. 3 is a circuit diagram of a switched-capacitor current reference in an embodiment.

FIG. 4 is diagram illustrating voltage waveforms at several nodes of a switched-capacitor current reference in an embodiment.

FIG. 5 is a diagram illustrating the implementation of a feedback circuit used in a switched-capacitor current reference in another embodiment.

FIG. 6 is a circuit diagram of a switched-capacitor current reference in another embodiment.

The drawing in which an element first appears is indicated by the leftmost digit(s) in the corresponding reference number.

### DETAILED DESCRIPTION

1. Example Device

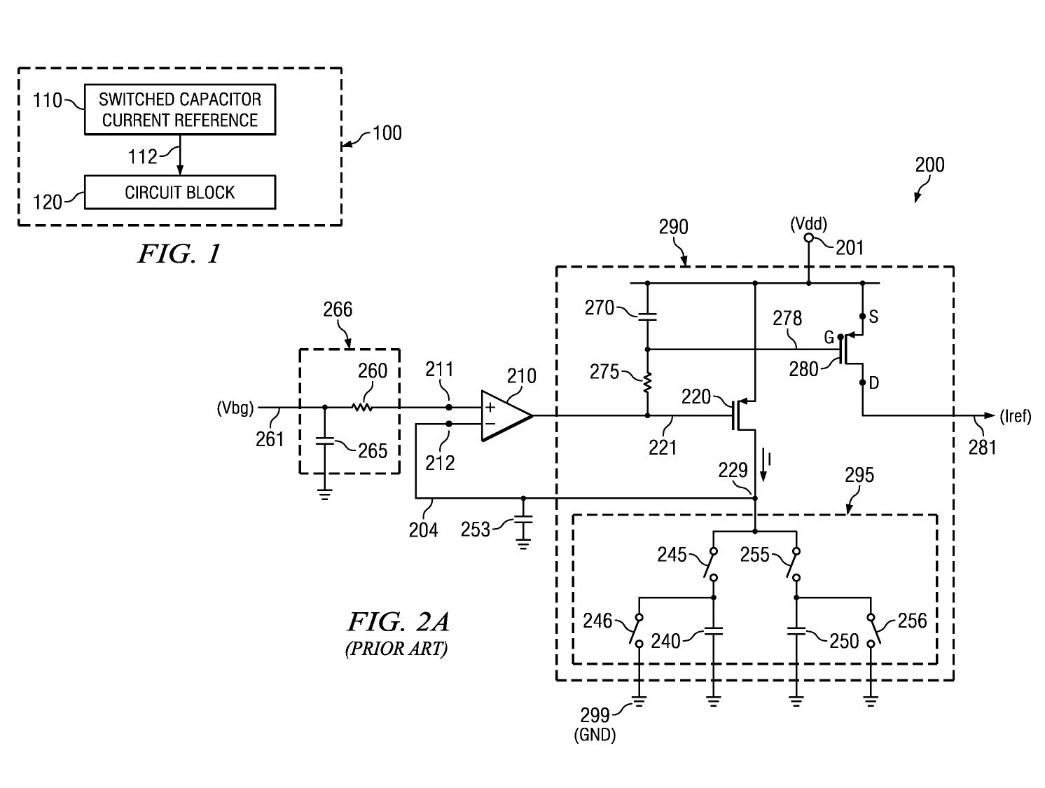

FIG. 1 is a block diagram of an example device in which several embodiments can be implemented. The block diagram shows a device 100, in turn shown containing a switched-capacitor current reference 110 and circuit block 120. Device 100 may correspond to any device that is implemented using switched-capacitor current references. For example, device 100 may correspond to a digital to analog converter (DAC) that uses current references in the process of converting a digital value to a corresponding (analog) current (or voltage) level. Circuit block 120 thus corresponds to a circuit block(s) of device 100 that use the output of switched-capacitor current reference 110. Device 100 may be implemented in integrated circuit (IC or SoC) form, or using discrete components. The components/blocks of device 100 in FIG. 1 are shown merely by way of illustration. Device 100 may contain more or fewer components/blocks than those shown in FIG. 1.

Switched-capacitor current reference 110 provides a constant reference current on path 112. Circuit block 120 uses the constant reference current received on path 112, and operates to provide the corresponding functions it is designed to provide. Some of the features of switched-capacitor current reference 110 will be clearer in comparison with a prior circuit, and accordingly the prior circuit is described first.

2. Prior Circuit

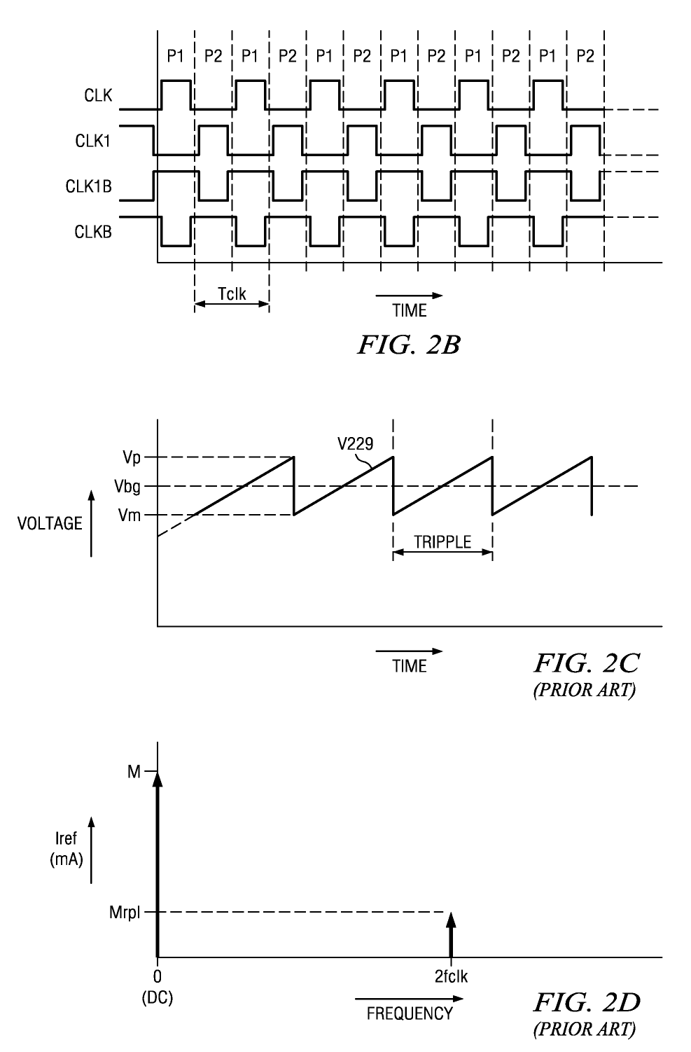

FIG. 2A is a circuit diagram of a switched-capacitor current reference in a prior embodiment. Switched-capacitor current reference 200 there is shown containing amplifier 210, filter 266, current mirror circuit 290 and capacitor 253. The output (constant reference current Iref) of circuit 200 is provided on terminal 281. Terminal 281 of FIG. 2A corresponds to output terminal/path 112 of FIG. 1.

Current mirror circuit 290 is shown containing switched-capacitor block 295, transistors 220 and 280, capacitor 270 and resistor 275. A constant reference voltage (for example, as may be obtained from the output of a band gap reference, not shown) is provided at node 261 (Vbg). Gate, source and drain terminals of transistor 280 are respectively marked G, S and D. Terminals of other transistors are also labeled with similar convention, when required. Power and ground terminals are marked 201 (Vdd) and 299 (GND) respectively. Transistors 220 and 280 may each be implemented as P-type metal oxide semiconductor (PMOS) transistors.

Input terminal 211 of amplifier 210 is maintained (substantially constant) at a voltage equal to Vbg. The output terminal 221 of amplifier 210 is connected to the gate (control) terminal of transistor 220. Input terminal 212 of amplifier 210 is connected to node 229. Amplifier 210 (which may, for example, be implemented as an operational amplifier (OPAMP)) is connected in a feedback configuration, as shown in FIG. 2A, and operates to maintain the average value of node 229 at a voltage equal Vbg. Voltages at input terminals 211 and 212 (node 212 being electrically the same as node 229) also equal Vbg. Capacitor 270 is used to provide frequency compensation, and the combination of capacitor 270 and resistor 275 (in addition to providing a zero in closed loop dynamics of the circuit of FIG. 2A) operates as an RC-filter to minimize variations in the value of Iref.

In operation, switched-capacitor block 295 of current mirror circuit 290 serves as a resistance (R), and the current (indicated as ‘I’ in FIG. 2A) through transistor 220 has an average value of (Vbg/R). The voltage at the gate terminal of transistor 280 equals the difference of the voltage at node 221 and the product (L_{leakage}*R275), wherein R275 represents the resistance of resistor 275, I_{leakage} being the gate leakage current of transistors 220 and 280 and compensation capacitor 270. The voltage at the gate terminal of transistor 220 being different from the voltage at node 221, the current (output reference current Iref) that would flow out of terminal 281 differs from (Vbg/R) by a corresponding fixed offset, the fixed offset equaling the product of voltage (L_{leakage}*R275) and the transconductance (Gm) of transistor 280.

Capacitors 240 and 250 (which may be implemented to have the same capacitance value) of switched-capacitor block 295 are alternately charged and discharged, by corresponding opening and closing of switches 245, 246, 255 and 256. Switches 245, 246, 255 and 256 are respectively controlled by clocks CLK, CLKB, CLK1 and CLK1B, shown in FIG. 2B. It is assumed that a logic high value of a clock closes the corresponding switch, while a logic low value closes the switch.

Thus, during phase P1, CLK is at logic high, switch 245 is closed, CLKB is at logic low, switch 246 is open, and capacitor 240 charges due to current I. During phase P1, CLK1 is at logic low, switch 255 is open, CLK1B is at logic high, switch 256 is closed, and capacitor 250 discharges (the charge stored in an earlier charging cycle) to ground. During phase P2, CLK is at logic low, switch 245 is open, CLKB is at logic high, switch 246 is closed, and capacitor 240 discharges to ground 299. During phase P2, CLK1 is at logic high, switch 255 is closed, CLK1B is at logic low, switch 256 is open, and capacitor 250 charges due to current I.

CLK and CLK1 are non-overlapping clocks. CLKB and CLK1B are respectively the inverse of clocks CLK and CLK1. The frequencies of clocks CLK, CLKB, CLK1 and CLK1B (and thus the duration of charge and discharge of capacitors 240 and 250) and the capacitances of capacitors 240 and 250 determine the equivalent resistance value ‘R’ (noted above) offered by switched-capacitor block 295. The values of the capacitances of capacitors 240 and 250 and the clock frequencies may be selected to obtain a desired value for ‘R’, and therefore for a corresponding desired value of output reference current Iref provided on path 281. Phases P1 and P2 repeat as shown in FIG. 2B.

The operation of the switched-capacitor block 295 as noted above causes the voltage at node 229 to vary as shown in FIG. 2C, in which the steady state voltage (V229) at node 229 is shown. Voltage (V229) rises to a peak level Vp when one of the two capacitors 240 and 250 charges along with capacitor 253, the other of the two capacitors 240 and 250 discharging to GND (229) in the duration of ramp up to Vp. At the start of the next phase, voltage (V229) drops to a minimum level Vm due to charge sharing between Capacitor 253 and the capacitor which was discharged to ground in the previous clock phase. Voltage V229 is shown as a ramp waveform varying between a peak (Vp) and minimum (Vm) voltage. The extent of variation (Vp-Vm) decreases (due to charge sharing with capacitor 253) with larger values of capacitor 253 (in comparison with capacitors 240 and 250). Variation (Vp-Vm) also decreases as the value of Vbg (261) is reduced. As noted above, the circuit of FIG. 2A operates to maintain the average value of the voltage at node 229 equal to Vbg volts, as also indicated in FIG. 2C. However, the instantaneous values of voltage V229 vary as shown by the ramp waveform in FIG. 2C.

Due to the feedback path 204 from node 229 to input 212 of amplifier 210, amplifier 210 causes output voltage at node 221 to change correspondingly, so as to maintain nodes 211 (which would have a voltage Vbg) and 212 at the same voltage. Variations in the voltage at node 221 in turn cause corresponding variations (ripple) in current I, and therefore in the (mirrored) output reference current Iref at node 281. The frequency of the variations (ripple) in voltage V229 have a frequency twice that of any of the clocks CLK, CLKB, CLK1 and CLK1B, and correspondingly the variations in the value of the output reference current Iref has (in addition to the desired DC component), a ripple component having a non-zero value at a frequency twice that of any of the clocks (i.e., 2*(1/Tclk) or 2*fclk), Tclk as shown in FIG. 2B). In general, larger the variations in voltage V229, larger would be the ripple in reference current Iref (281).

The frequency components of reference current Iref (281) are shown in FIG. 2D. Reference current Iref (281) is shown as having a DC component with magnitude ‘M’ milli-amperes (mA), and a ripple component at frequency (2*fclk) with magnitude ‘Mrpl’. The variations or ripple in the magnitude of reference current Iref may not be desirable. Another drawback with the prior circuit of FIG. 2 is that the variations at terminal 212 of amplifier 210 may be coupled to terminal 211 due to parasitic capacitance between terminals 211 and 212. The parasitic capacitance may be present within or external to amplifier 210. To prevent the ‘coupled’ variations at node 211 from affecting Vbg (261), RC filter 266 (containing resistor 260 and capacitor 265) is used. Implementation of RC filter 266 increases the area required for implementing current reference 200.

The magnitude of ripple ‘Mrpl’ may be reduced by techniques such as increasing the capacitance of capacitor 253 (which may require a larger implementation area and a greater value of capacitor 270 for stability in operation of amplifier 210), reducing the transconductance ‘Gm’ of transistors of the input stage of amplifier 210 (which may result in more thermal noise and sensitivity of the input stage (as well as Iref) to temperature variations), and decreasing the cut-off frequency of the filter formed by capacitor 270 and resistor 275 (which may require larger capacitance value for compensation capacitor 270 and hence larger implementation area, and be associated with temperature-dependant voltage drop across resistor 275 due to gate leakage currents of transistors 220 and 280). The above approaches to reducing ripple in Iref may not be desirable at least for the reasons noted above.

3. Switched-Capacitor Current Reference with Reduced Ripple Component

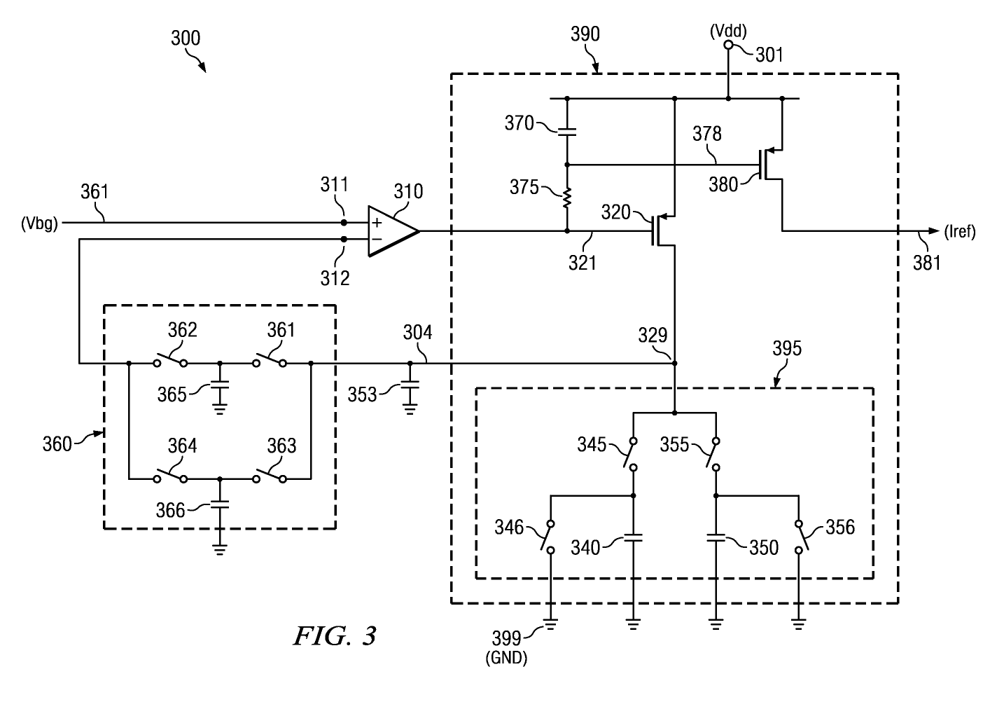

FIG. 3 is a circuit diagram of a switched-capacitor current reference in an embodiment. Switched-capacitor current reference 300 of FIG. 3 is shown containing amplifier 310, current mirror circuit 390, feedback circuit 360 and capacitor 353. The output (constant reference current Iref) of circuit 300 is provided on terminal 381, which corresponds to output terminal/path 112 of FIG. 1.

Current mirror circuit 390 is shown containing switched-capacitor block 395, transistors 320 and 380, capacitor 370 and resistor 375. Current mirror circuit 390 operates in a manner similar to current mirror circuit 290 of FIG. 2A, with switched-capacitor block 395, CMOS transistors 320 and 380, capacitor 370 and resistor 375 corresponding respectively to switched-capacitor block 295, CMOS transistors 220 and 280, capacitor 270 and resistor 275 of FIG. 2A. Transistors 320 and 380 may each be implemented as P-type metal oxide semiconductor (PMOS) transistors. In, operation, switched-capacitor block 395 may be viewed as a resistor, and accordingly node 329 of FIG. 3 may also be referred to as a terminal of the “resistor”, the other terminal of the “resistor” being connected to ground (GND) 399. Terminals 311 and 312 respectively represent the non-inverting and inverting inputs of amplifier 310.

Input terminal 311 of amplifier 310 is maintained (substantially constant) at a voltage equal to Vbg, received on path 361. Output terminal 321 of amplifier 310 is connected to the gate (control) terminal of transistor 320. Amplifier 310 (which may, for example, be implemented as an OPAMP) is connected in a feedback configuration, as shown in FIG. 3, and generates voltages on output 321 to maintain the voltage at input terminal 312 equal to the voltage Vbg at input terminal 311. Capacitor 370 is used to provide frequency compensation, and the combination of capacitor 370 and resistor 375 (in addition to creating a zero in the closed loop dynamics of the circuit of FIG. 3) operates as an RC-filter to minimize variations in the value of Iref provided on output path 381.

Capacitors 340 and 350 of switched-capacitor block 395 are alternately charged and discharged, by corresponding opening and closing of switches 345, 346, 355 and 356. Switches 345, 346, 355 and 356 are respectively controlled by clocks CLK, CLKB, CLK1 and CLK1B, shown in FIG. 2B. Capacitors 340 and 350 may be implemented to have the same capacitance value, which equals 0.925 picoFarads in an embodiment.

Feedback circuit 360 is shown containing capacitors 365 and 366 and switches 361, 362, 363 and 364. The opening and closing of switches 361, 362, 363 and 364 is controlled respectively by the logic level of clocks CLK, CLKB, CLK1 and CLK1B. Thus, each of switch pairs (345 and 361), (346 and 362), (355 and 363) and (356 and 364) open and close in synchronism. Capacitors 365 and 366 may be implemented to have the same capacitance value, which equals 1.4 picoFarads in an embodiment.

In operation, each of capacitors 340 and 350 charges and discharges during corresponding phases of the respective clocks as described above with respect to charging and discharging of capacitors 240 and 250 of FIG. 2A respectively, and the description is not repeated here in the interest of conciseness.

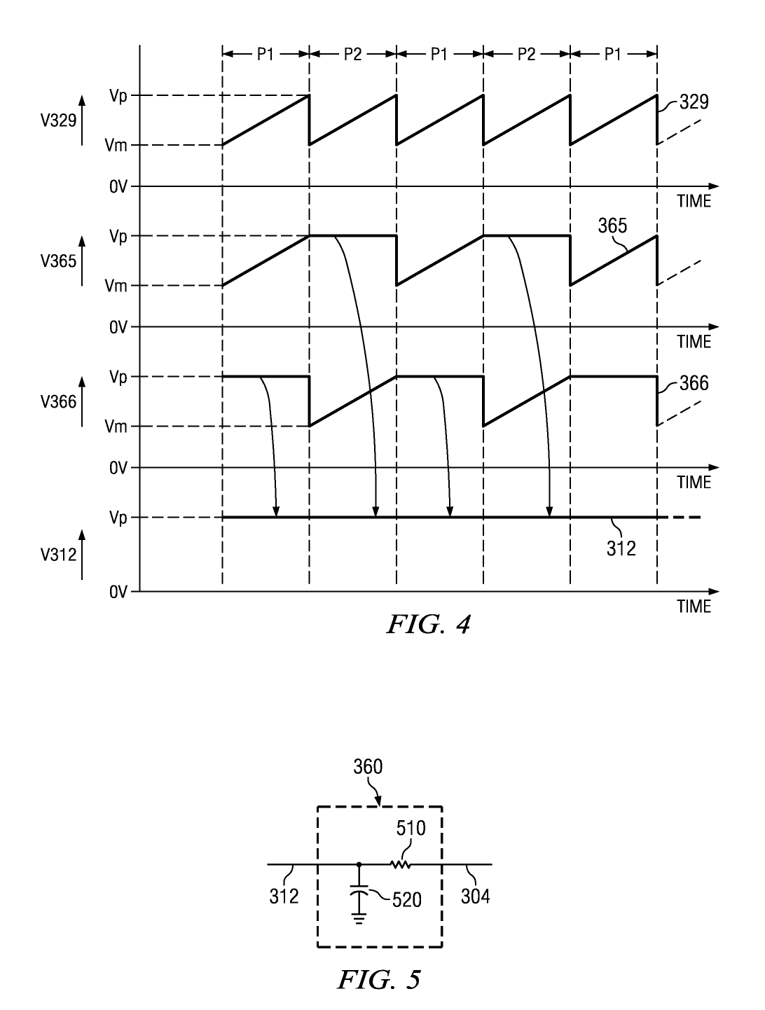

FIG. 4 is a timing diagram illustrating the voltages (at steady state) at several nodes of the circuit of FIG. 3. The time axes for voltage waveforms (V329, V365, V366 and V312) of FIG. 4 are assumed to be on the same scale. In the steady state, the voltage (V329) at node 329 varies as shown. Phases P1 and P2 of FIG. 4 correspond in time to phases P1 and P2 shown in FIG. 2B.

In phase P1, switches 345, 356, 361 and 364 are closed, and switches 355, 346, 362 and 363 are open. As a result, each of capacitors 340 and 365 charges to a peak voltage Vp, and voltages V329 and V365 ramp up from a voltage Vm to voltage Vp. Capacitor 366 is assumed (in steady state) to have charged in the previous P2 phase to voltage Vp. Hence, switch 364 being closed in the ‘current’ phase P1, the voltage at node 312 is maintained at a value Vp in phase P1. Capacitor 350 is discharged to zero volts (GND (399)) in phase P1.

In phase P2, switches 355, 346, 363 and 362 are closed, and switches 345, 356, 361 and 364 are open. As a result, each of capacitors 350 and 366 charges to a peak voltage Vp. At the start of phase P2, voltage V329 is Vp, and quickly falls (shown as an instantaneous drop, but which may in practice have a finite fall time, however small) to Vm, due to charge sharing with capacitor 353 when capacitor 350 is connected to node 329 (capacitor 350 having been discharged to ground by the end of phase P1). Closure of switches 355 and 363 causes capacitors 350 and 366 to charge from Vm to Vp, and voltages V329 and V366 ramp up from voltage Vm to voltage Vp. Capacitor 365, having charged to voltage Vp in the previous P1 phase, and switch 362 being closed in the ‘current’ P2, the voltage at input 312 of amplifier 310 continues to be maintained at value Vp in phase P2 as well. Capacitor 340 is discharged to 0 volts in phase P2.

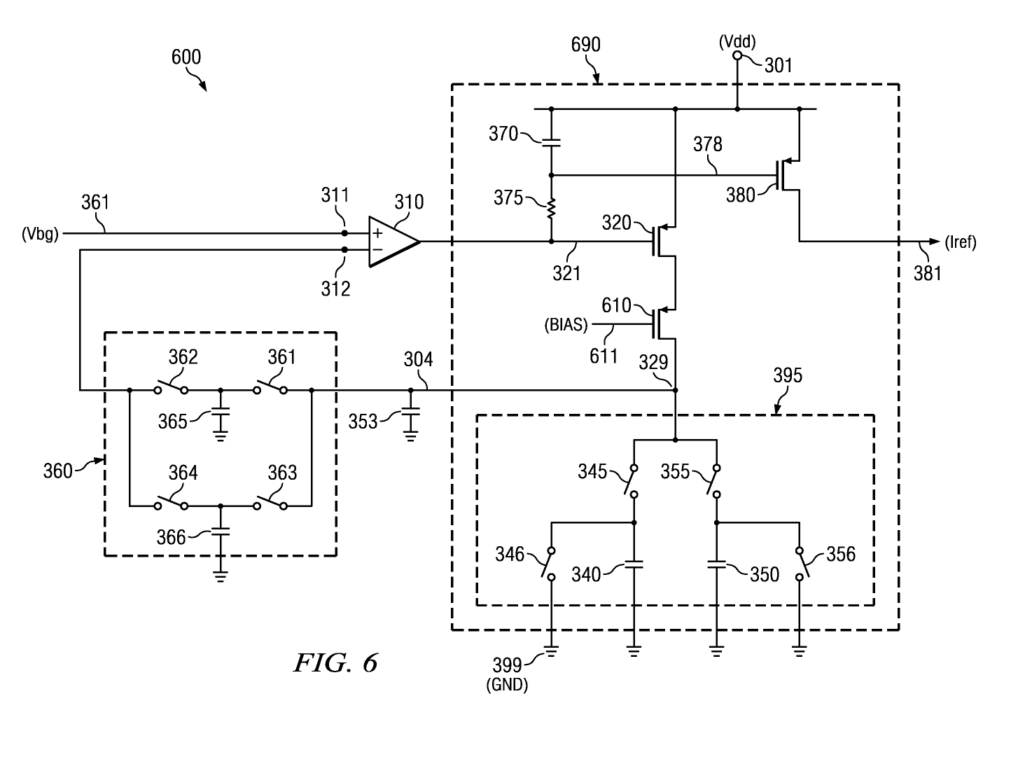

Phases P1 and P2 repeat as shown in FIG. 4, and the voltage at input 312 of amplifier 310 continues to be maintained at a constant value of Vp, or at least the variations of the voltage at input terminal 312 are minimized to a large extent. Thus, it may be appreciated that variations (Vp-Vm) at node 329 are prevented from being presented at input 312 of amplifier 310 due to operation of feedback circuit 360 (in conjunction with switched-capacitor block 395), and variations that otherwise might have been caused (due to response of amplifier 310 to the variations) in output Iref (381) are prevented from occurring. It is noted, however, that the variations at node 329 may be coupled from the drain terminal (same as node 329) of transistor 320 to the gate terminal (321) of transistor 320 due to presence of parasitic capacitance (not shown) between the gate and drain terminals of transistor 320. The coupling of the variations to gate terminal 321 may cause output Iref (381) to vary. Such variations may be minimized by cascading transistor 320, as shown in FIG. 6, in which current mirror circuit 390 is replaced by current mirror circuit 690. The circuit and connections of switched-capacitor current reference 600 of FIG. 6 are identical to that of FIG. 3, except for the addition of cascode transistor 610 in current mirror circuit 690. Cascode transistor 610 is shown connected between node 329 and the drain terminal of transistor 320. Gate terminal 611 of cascode transistor 610 receives a fixed bias voltage (bias). Cascode transistor 610 minimizes coupling of variations at node 329 to the gate terminal 321 of transistor 320. Variations at node 329 are further minimized by the RC Filter (operating as a low-pass filter) formed by resistor 375 and capacitor 370.

It may be appreciated that the voltage at terminal 312 of amplifier 310 is maintained substantially constant (ignoring variations due to inherent noise) at a value Vp (which equals Vbg (361)), or at least the variations at terminal 312 are largely minimized, due to operation of the feedback-loop configuration of amplifier 310. Hence, in contrast to the circuit of FIG. 2A (in which the variations at node 229 are passed unprocessed/unmodified via the feedback loop to the input of amplifier 210), in the circuit of FIG. 3, the variations at node 329 may be viewed as being processed/modified, and only the peak value Vp is provided via the feedback path to amplifier input 312. As a result, the output of amplifier 310 is also maintained substantially constant, and the values of current through transistor 320, and hence the reference output current (Iref) on path 381 is also maintained substantially constant (or at least variations in Iref are minimized). As a result, Iref (381) may have only a DC component, or have only a very low-magnitude component at frequency (2*fclk) in addition to a DC component, in contrast to the relatively larger component at (2*fclk) of the prior current reference output of FIG. 2A.

The implementation of current reference 300 as described above provides several advantages, some of which are briefly noted next.

Capacitor 353 may be implemented to have a small capacitance, unlike capacitor 253 of FIG. 2A which may be required to have a large value. Capacitor 353 needs to be implemented with a capacitance value sufficient enough only to prevent voltage V329 from shooting up (rising sharply) in the non-overlap time between clocks CLK and CLK1 (i.e. in the interval when both clocks CLK and CLK1 are at logic zero), due to the overall small value of capacitance (e.g., parasitic capacitance, that may be present between node 329 and GND (399)). As a result, area required to implement capacitor 353 is reduced. In an embodiment, capacitor 353 is implemented to have a capacitance of 400 femtoFarads. Compensation capacitor 370 (which sets the unity gain bandwidth (UGB) of amplifier 310, and hence the dynamics of amplifier 310 in reducing variations in voltage at node 321) may also be implemented to have a small capacitance, and therefore with a smaller area. As an example illustration, assuming a desired maximum (target) ripple of 80 dB at node 329, the circuit of FIG. 2A may need to be implemented with each of capacitors 270 and 253 having a value of 50 picoFarads (pF), whereas the circuits of FIG. 3 (and FIG. 6) may need to implemented with capacitors C370 and C353 with values of only 7 pF and 0.4 pF respectively.

Filtering requirement of RC filter formed by resistor 375 and capacitor 370 is smaller (i.e., larger cut-off frequency). Hence resistor 375 may be implemented to have a smaller value, resulting in reduced temperature dependence (due to smaller temperature coefficient) of the gate leakage currents of transistors 320 and 380 through resistor 375, and thereby rendering implementation of current reference 300 easier in UDSM (ultra-deep sub-micron) process, which is generally associated with larger gate leakage currents.

Amplifier 310 may be designed with large transconductance (Gm) value for transistors in its input stage, and thereby with reduced thermal noise and input offset. The reduced input offset in amplifier 310 enables a corresponding reduced temperature-dependent variation in Iref (381). The gain-bandwidth product (GBW) of amplifier 310 may be implemented to be large.

Since input 312 of amplifier 310 is maintained at a constant voltage Vp, coupling (due to parasitic capacitance) of the voltage variations at terminal 312 to terminal 311 is minimized or eliminated. As a result, implementation of an RC filter between the output of a device providing Vbg (361) terminal 311 may be eliminated, thereby resulting in further reduction of area for implementing current reference 300.

Smaller value of capacitors 370 and 353, larger Gm of transistors in the input stage of amplifier 310 and larger GBW of amplifier 310 enable current reference 300 to quickly settle to a steady state of operation from the instance of power-ON or after transient disturbances due to noise.

Switched-capacitor current references 300 or 600 may be implemented in place of component/circuit 110 of device 100 of FIG. 1.

It may be noted that feedback circuit 360 operates as a sample-and-hold circuit, and the feedback loop (closed path formed by (amplifier 310-output 321-node 329-feedback circuit 360-input 312 of amplifier 310) operates as a time-discretized (or discrete-time) feedback loop. Accordingly, feedback circuit 360 may also be viewed as a discrete-time or time-discretized feedback circuit. In an alternative embodiment, feedback circuit 360 is implemented as an RC filter, as shown in FIG. 5. The RC filter is implemented using resistor 510 and capacitor 520. It is noted that the implementation of feedback circuit 360 as an RC filter may only minimize the variations in the voltage at terminal 312, rather than maintain the voltage steady as in the implementation of FIG. 3, and may be associated with larger implementation area.

It should be appreciated that the specific type of transistors (such as NMOS, PMOS, etc.) noted above are merely by way of illustration. However, alternative embodiments using different configurations and transistors will be apparent to one skilled in the relevant arts by reading the disclosure provided herein. For example, the NMOS transistors may be replaced with PMOS (P-type MOS) transistors, while also interchanging the connections to power and ground terminals.

Accordingly, in the instant application, the power and ground terminals are referred to as constant reference potentials, the source (emitter) and drain (collector) terminals of transistors (though which a current path is provided when turned on and an open path is provided when turned off) are termed as current terminals, and the gate (base) terminal is termed as a control terminal.

Furthermore, though the terminals are shown with direct connections to various other terminals, it should be appreciated that additional components (as suited for the specific environment) may also be present in the path, and accordingly the connections may be viewed as being electrically coupled to the same connected terminals.

While various embodiments of the present invention have been described above, it should be understood that they have been presented by way of example only, and not limitation. Thus, the breadth and scope of the present invention should not be limited by any of the above-described embodiments, but should be defined only in accordance with the following claims and their equivalents.

What is claimed is:

1. A switched-capacitor circuit comprising:
an amplifier to generate an amplified output as the difference of a feedback signal and a constant reference voltage, the amplifier receiving the constant reference voltage on a first input terminal and the feedback signal on a second input terminal;
a current mirror circuit to receive the amplified output and to provide a reference current as an output on an output node of the switched-capacitor circuit, the current mirror circuit comprising a switched-capacitor block that offers a resistance to set the value of the reference current, the value of the reference current being also based on the constant reference voltage; and
a feedback circuit operating to receive a time-varying voltage waveform at a first node in the current mirror circuit and to generate the feedback signal as a constant voltage, wherein the first node is a first terminal of a first resistor represented by the switched-capacitor block.

2. The switched-capacitor circuit of claim 1, wherein the feedback circuit comprises a discrete time block comprising a plurality of capacitors, a first set of switches and a second set of switches,
wherein the first set of switches are operated to couple the plurality of capacitors to the second input terminal, wherein the second set of switches are operated to couple the plurality of capacitors to the first node, such that the time-varying voltage waveform is presented as a constant voltage on the second input terminal of the amplifier, the first set of switches and the second set of switches being operated in response to corresponding clock signals.

3. The switched-capacitor circuit of claim 2, wherein the switched-capacitor block comprises a first capacitor and a second capacitor, and the plurality of capacitors in the feedback circuit comprises a third capacitor and a fourth capacitor,
wherein the first capacitor and the third capacitor are each coupled to the first node during a first phase of operation, the second capacitor being coupled to a first constant reference potential during the first phase of operation, and the fourth capacitor being coupled to the second input terminal of the amplifier in the first phase of operation, and
wherein the second capacitor and the fourth capacitor are each coupled to the first node during a second phase of operation, the first capacitor being coupled to the first constant reference potential during the second phase of operation, and the third capacitor being coupled to the second input terminal of the amplifier in the second phase of operation,
whereby the feedback signal has a constant voltage.

4. The switched-capacitor circuit of claim 3, wherein the current mirror circuit further comprises:
a first transistor, a second transistor, a second resistor and a fifth capacitor,
wherein a control terminal of the first transistor is coupled to an output terminal of the amplifier to receive the amplified output, a first current terminal of the first transistor being coupled to a second constant reference potential, and a second current terminal of the first transistor being coupled to the first node,
wherein a first terminal of the second resistor is coupled to the output terminal of the amplifier, a second terminal of the second resistor being coupled to a first terminal of the fifth capacitor, and
wherein the second terminal of the fifth capacitor is coupled to the second constant reference potential, wherein the combination of the second resistor and the fifth capacitor operates as a low-pass filter.

5. The switched-capacitor circuit of claim 4, wherein a control terminal of the second transistor is coupled to the second terminal of the second resistor, a first current terminal of the second transistor being coupled to the second constant reference potential, and wherein a second current terminal of the second transistor is the output node providing the reference current.

6. The switched-capacitor circuit of claim 5, further comprising a sixth capacitor coupled between the first node and the first constant reference potential, the sixth capacitor operating to control the voltage at the first node in a non-overlap time between a first clock and a second clock operating to couple or decouple the first capacitor and the second capacitor from the first node.

7. The switched-capacitor circuit of claim 6, wherein the amplifier is implemented to have a high gain bandwidth product (GBW), wherein the values of the capacitance of the sixth capacitor and resistance of the second resistor are designed to be low,
whereby the settling time of the circuit is short.

8. The switched-capacitor circuit of claim 6, wherein the current mirror circuit further comprises a third transistor coupled in series configuration with the first transistor, to minimize coupling of the variations from the first node to the control terminal of the first transistor,
wherein, a control terminal of the third transistor is coupled to a bias voltage, a first current terminal of the first transistor is coupled to the second current terminal of the third transistor, and a second current terminal of the third transistor is coupled to the first node.

9. The switched-capacitor circuit of claim 8, wherein the constant reference voltage on the first input terminal of the amplifier is provided by a band-gap reference circuit.

10. A device comprising:
a circuit designed to receive a reference current as an input, and providing a desired circuit function; and
a switched-capacitor circuit for providing the reference current to the circuit block, the switched-capacitor circuit comprising:
an amplifier to generate an amplified output as the difference of a feedback signal and a constant reference voltage, the amplifier receiving the constant reference voltage on a first input terminal and the feedback signal on a second input terminal;
a current mirror circuit to receive the amplified output and to provide a reference current as an output on an output node of the switched capacitor circuit, the current mirror circuit comprising a switched-capacitor block that offers a resistance to set the value of the reference current, the value of the reference current being also based on the constant reference voltage; and
a feedback circuit operating to receive a time-varying voltage waveform at a first node in the current mirror circuit and to generate the feedback signal as a constant voltage, wherein the first node is a first terminal of a first resistor represented by the switched-capacitor block.

11. The device of claim 10, wherein the feedback circuit is implemented as a discrete-time block comprising a plurality of capacitors, a first set of switches and a second set of switches,
wherein the first set of switches are operated to couple the plurality of capacitors to the second input terminal, wherein the second set of switches are operated to couple the plurality of capacitors to the first node, such that the time-varying voltage waveform is presented as a constant voltage on the second input terminal of the amplifier, the first set of switches and the second set of switches being operated in response to corresponding clock signals.

12. The device of claim 11, wherein the switched-capacitor block comprises a first capacitor and a second capacitor, and the feedback circuit comprises a third capacitor and a fourth capacitor,
wherein the first capacitor and the third capacitor are each coupled to the first node during a first phase of operation, the second capacitor being coupled to a first constant reference potential during the first phase of operation, and the fourth capacitor being coupled to the second input terminal of the amplifier in the first phase of operation, and
wherein the second capacitor and the fourth capacitor are each coupled to the first node during a second phase of operation, the first capacitor being coupled to the first constant reference potential during the second phase of operation, and the third capacitor being coupled to the second input terminal of the amplifier in the second phase of operation,
whereby the feedback signal has a constant voltage.

13. The device of claim 12, wherein the current mirror circuit further comprises:
a first transistor, a second transistor, a second resistor and a fifth capacitor,
wherein a control terminal of the first transistor is coupled to an output terminal of the amplifier to receive the amplified output, a first current terminal of the first transistor being coupled to a second constant reference potential, and a second current terminal of the first transistor being coupled to the first node,
wherein a first terminal of the second resistor is coupled to the output terminal of the amplifier, the second terminal of the second resistor being coupled to a first terminal of the fifth capacitor, and
wherein the second terminal of the fifth capacitor is coupled to the second constant reference potential.

14. The device of claim 13, wherein a control terminal of the second transistor is coupled to the second terminal of the second resistor, a first current terminal of the second transistor being coupled to the second constant reference potential, and wherein a second current terminal of the second transistor is the output node providing the reference current.

15. The device of claim 14, further comprising a sixth capacitor coupled between the first node and the first constant reference potential.

16. The device of claim 15, wherein the amplifier is implemented to have a high gain bandwidth product (GBW), wherein the values of the capacitance of the sixth capacitor and resistance of the second resistor are designed to be low,
whereby the settling time of the switched-capacitor circuit is short.

17. The device of claim 15, wherein the current mirror circuit further comprises a third transistor coupled in series configuration with the first transistor,
wherein, a control terminal of the third transistor is coupled to a bias voltage, a first current terminal of the first transistor is coupled to the second current terminal of the third transistor, and a second current terminal of the third transistor is coupled to the first node.

18. The device of claim 17, wherein the constant reference voltage on the first input terminal of the amplifier is provided by a band-gap reference circuit.
